(19) United States
(12) Patent Application Publication
(10) Pub. No.: US 2026/0206523 A1
(43) Pub. Date: Jul. 16, 2026

(54) ZONAL WINDOW CONTROL TO IMPROVE WAFER FILM THICKNESS UNIFORMITY

(71) Applicant: Applied Materials, Inc., Santa Clara, CA (US)

(72) Inventors: Chengen WANG, Cupertino, CA (US); Mrunmayi MUNGEKAR, Santa Clara, CA (US); Chidambara A. RAMALINGAM, Fremont, CA (US); Marc SHULL, San Jose, CA (US); Wei-Sheng LEI, San Jose, CA (US); Juan C. ROCHA, San Carlos, CA (US)

(21) Appl. No.: 19/019,417

(22) Filed: Jan. 13, 2025

(51) Int. Cl. H01L 21/67; H05B 3/02

(52) U.S. Cl. CPC H10P 72/0436; H05B 3/02

(57) ABSTRACT

A window for use in a processing chamber applicable for use in semiconductor manufacturing, including a first zone disposed between a first radius and a second radius including a first transmissivity and a second zone disposed between the second radius and a third radius including a second transmissivity.

### BACKGROUND

### Field

Embodiments of the present disclosure generally relate to chambers, methods, systems, and related components for modifying heat temperatures in relation to substrate processing for semiconductor manufacturing.

### Description of the Related Art

Semiconductor wafers are processed for a wide variety of applications, including the fabrication of integrated devices and micro-devices. Wafers can undergo a variety of processing operations, which can involve high temperature operations. As an example, wafers can be heated by energy emitted by heating devices within processing chambers in order to cure films on a wafer. The energy transmitted to the wafers from these heating devices may not be uniform which can lead to non-uniform curing of said films. Non-uniform curing can lead to non-uniform film shrinkage and, accordingly, non-uniform film thicknesses.

Therefore, a need exists for chambers, systems, and methods that facilitate modifying the energy transmitted to discrete locations on such wafers to improve uniformity of film thicknesses.

### SUMMARY

Embodiments of the present disclosure relate to chambers, methods, systems, and related components for improving wafer film thickness uniformity.

In one or more embodiments, A window for use in a processing chamber applicable for use in semiconductor manufacturing, including a first zone disposed between a first radius and a second radius including a first transmissivity and a second zone disposed between the second radius and a third radius including a second transmissivity.

In one or more embodiments, A processing chamber applicable for use in semiconductor manufacturing, including a chamber body at least partially defining an internal volume, a pedestal disposed within the internal volume, one or more heat sources disposed within the internal volume and configured to emit energy towards the pedestal, and a window disposed between the one or more heat sources and the pedestal. The energy emitted by the one or more heat sources passes through the window. The window includes a first zone including a first transmissivity and a second zone including a second transmissivity, wherein the first transmissivity is less than the second transmissivity.

In one or more embodiments, A method of manufacturing a substrate processing chamber including determining a film disposed on a wafer in a processing chamber experiences non-uniform film shrinkage from one or more heat sources emitting energy through one or more windows, the non-uniform film shrinkage includes a first film shrinkage at a first location on the wafer and a second film shrinkage at a second location on the wafer and the method including modifying a transmissivity a first zone of the one or more windows corresponding to the first location on the wafer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a partial schematic side cross-sectional view of a processing system including a processing chamber, according to one or more embodiments.

FIG. 2A is a schematic top view of a wafer with an exemplary non-uniform film thickness, according to one or more embodiments.

FIG. 2B illustrates a chart plotting the film thickness delta across the radius of the wafer of FIG. 2A, according to one or more embodiments.

FIG. 3A is a schematic top view of a window including modified properties to adjust zonal transmissivity of the window that may be used to counteract the non-uniform film thicknesses illustrated in FIG. 2A, according to one or more embodiments.

FIG. 3B illustrates a chart comparing the film thickness delta of FIG. 2B to a film thickness delta of an exemplary wafer utilizing the window of FIG. 3A, according to one or more embodiments.

FIG. 4 illustrates a method for controlling the shrinkage of a film on a wafer, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to chambers, methods, systems, and related components for modifying wafer temperature profiles.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

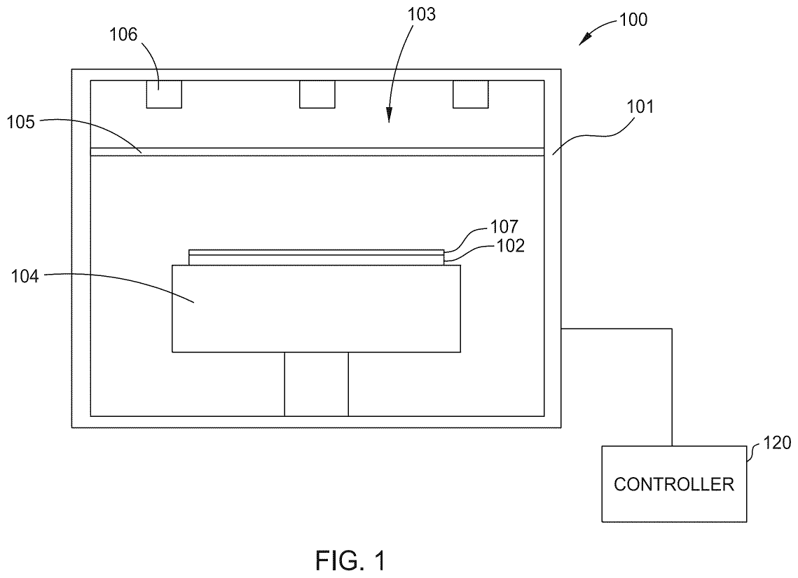

FIG. 1 is a partial schematic side cross-sectional view of a processing system including a processing chamber 100 and a controller 120. The illustrated processing chamber 100 is a curing chamber used to cure a film 107 deposited on a wafer 102. The controller 120 is communicatively coupled to the processing chamber and controls the operations of the processing chamber 100

The processing chamber 100 includes a chamber body 101 that at least partially defines an internal volume 103. Disposed within the internal volume 103 is a pedestal 104, a window 105, and plurality of heat sources 106. The present disclosure contemplates that the processing chamber 100 can be a processing chamber used for any number of processing operations, such as a curing chamber, a deposition chamber, an epitaxial chamber, or any number of chambers that utilize heat sources 106 to transmit energy (such as ultraviolet (UV)) through a window 105 to heat a wafer 102.

In the implementation shown in FIG. 1, the heat sources 106 are lamps operable to heat the internal volume 103 of the chamber 100. Other heat sources are contemplated, such as resistive heaters, light emitting diodes (LEDs), and/or lasers. In one or more embodiments, the heat sources 106 are configured to emit energy to increase the temperature of the wafer 102 for wafer processing, such as for curing a film 107 on the wafer 102. In one or more embodiments, the heat sources 106 emit ultraviolet (UV) energy to heat the wafer 102. While the heat source 106 in the implementation shown in FIG. 1 only illustrates heat sources 106 disposed at the top of the chamber 100, it is contemplated that there could be multiple heat sources 106 which could be disposed anywhere in the chamber 100 so long as they are configured to emit energy through a window 105 and towards the wafer 102 to heat the wafer 102.

The window 105 is disposed between the heat sources 106 and the pedestal 104. The window 105 is configured to direct energy emitted from the heat sources 106 towards the wafer 106. Thus, the window 105 includes a transparent, transmissive, or semi-transmissive material. In one or more embodiments, the window 105 includes quartz, such as fused silica glass. Although only one window 105 is illustrated, there may be multiple windows 105, and the windows 105 may be any structure or shape including, but not limited to, a flat plate or a dome. In one or more embodiments, there may be one or more heat sources 106 disposed in other areas of the internal volume 103. In such embodiments, there may be one or more windows 105 disposed between the pedestal 104 and the one or more heat sources 106. For instance, in embodiments including an epitaxial chamber or deposition chamber, the illustrated window 105 may be an upper window (or dome) and there may be additionally a lower window (or dome) with heat sources disposed on the bottom of the chamber 100.

As shown, the controller 120 is in communication with the processing chamber 110 and is used to control processes and methods, such as the operations of the methods described herein. The controller 120 may control one or more processes or operations of the chamber 100 using a direct control or alternatively, by controlling computers (or controllers) associated with the processing chamber 100 and its components. In operation, the controller 120 enables data collection and feedback from the chamber 100 and controller 120 to optimize performance of the system.

According to one mode of operation, a wafer 102 is disposed on top of the pedestal 104 and the one or more heat sources 106 emit energy through the window 105 towards the wafer 102 to heat the wafer 102. For instance, when the processing chamber 100 is a cure chamber, a wafer 102 containing an uncured film is disposed on the pedestal 104 and is exposed to energy, such as UV energy, from the one or more heat sources 106 through the window 105.

As the energy is emitted from the one or more heat sources 106, the energy is transmitted through the window 105 and towards the wafer 102 to cure the film 107. Occasionally, the film 102 can experience a non-uniform cure. When the film 107 cures non-uniformly, the film 107 may experience differing levels of shrinkage leading to different film thicknesses across the surface of the wafer 102 (e.g., one portion of the film 107 experiences more shrinkage during curing and another portion of the film 107 experiences less shrinkage during curing). As an example, without being bound by theory, non-uniform curing of the film 107 may be due to a non-uniform reaction to energy exposure. As a non-limiting example, a portion of the film 107 being exposed to more energy may experience more shrinkage (resulting in a lesser film thickness) than another portion of the film 107 being exposed to less energy (resulting in a greater film thickness). In other words, reducing the amount of energy exposure in high shrinkage areas of a film 107 may decrease film thickness shrinkage and increasing energy exposure in low shrinkage areas may increase film thickness shrinkage thus reducing overall film thickness non-uniformity.

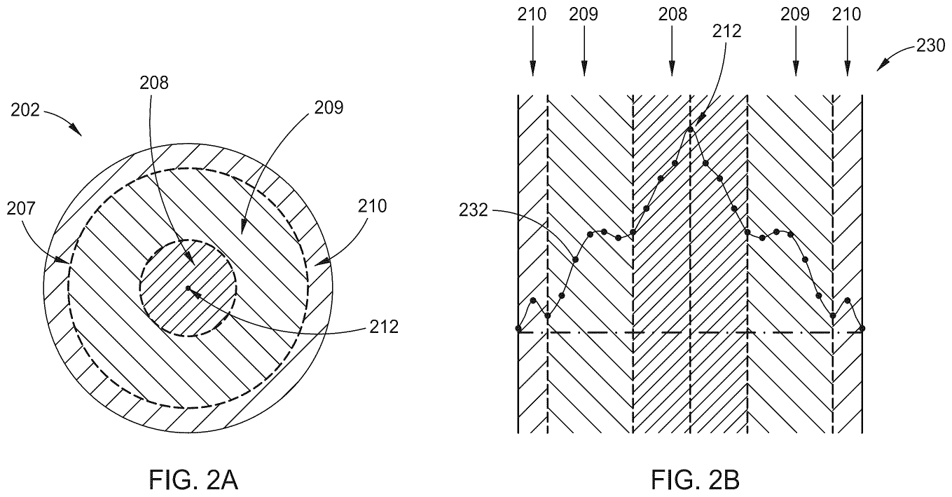

FIG. 2A is a schematic top view of a wafer 202 including an exemplary non-uniform film thickness. In the implementation illustrated in FIG. 2A, the thickness of the film 207 varies across the surface of the wafer 202. FIG. 2B illustrates a chart 230 plotting the film thickness delta 232 (e.g., shrinkage) (Y-axis) across the radius of the wafer 202 (X-axis).

In the illustrated embodiment, the wafer 202 includes a film 207 that has been cured in a curing chamber, such as exemplary curing chamber 100 illustrated in FIG. 1. The film 207 includes a non-uniform film thickness. That is, the film 207 experienced more shrinkage in certain locations leading to non-uniform film thickness due to non-uniform curing. For instance, as illustrated, the film 207 experienced different film shrinkage in locations 208, 209, and 210. As shown in chart 230, location 208 experienced the most shrinkage (e.g., the highest thickness delta). Also as shown in chart 230, location 209 experienced the second most shrinkage (e.g., the second highest thickness delta). Further, location 210 experienced the third most shrinkage (e.g. the third highest thickness delta). In one or more embodiments, such as the illustrated embodiment, the locations are defined by radius bands. In one or more embodiments, the shrinkage may vary by radius due to the plurality of heat sources rotating about the central axis of the wafer 202 leading to axisymmetric uniformity.

In one or more embodiments, locations 208 may be located between the center 212 of the window 105 and less than about 100% of the total radius of the window 105 such as between the center 212 of the window 105 and less than about 33% or less than about 25% of the total radius of the window 105. In one or more embodiments, the location 209 may be located between location 208 and less than about 100% of the total radius of the window 105 such as between location 208 and less than about 80% or less than about 75% of the total radius of the window 105. In one or more embodiments, location 210 may be located between location 209 and the outer diameter of the wafer 202. In one or more embodiments, the locations 208, 209, 210 may also be defined by percentage of diameter rather than percentage of radius.

As previously indicated, the illustrated locations 208, 209, 210 are illustrative and there may be more or less locations with varying film shrinkage at various, radial or non-radial, locations on the wafer 202.

While the illustrated embodiment illustrates shrinkage varying by radius with the most shrinkage occurring near the center of the wafer 202, it is contemplated that the film 207 on a wafer 202 may experience any amount of shrinkage at any location on the surface of the wafer 202. As a non-limiting example, shrinkage may vary by radius (as shown in the illustrated embodiment) such that the locations of varying shrinkage are concentric about the center of the wafer 202 or there may be discrete locations of high or low shrinkage that are not concentric about the center of the wafer 202. Similarly, in one or more embodiments, the locations may not be circular but may be generally triangular, generally square, generally polygonal, or amorphous.

As previously mentioned, film shrinkage and non-uniformity due to curing may be controlled by controlling the amount of energy exposure in high or low shrinkage areas of the film 107. Accordingly, by altering the amount of energy exposure experienced by the film 207 at the various locations 208, 209, 210, the film shrinkage and non-uniformity can be controlled.

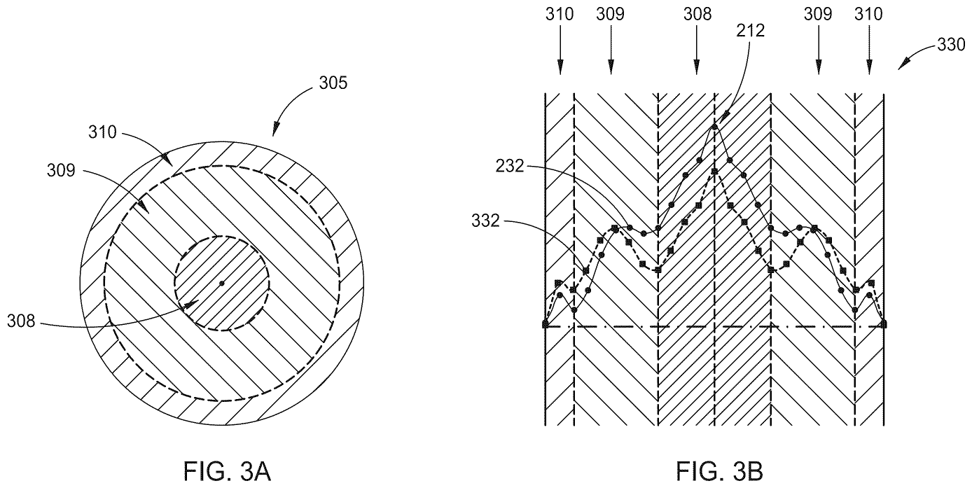

FIG. 3A is a schematic top view of a window 305 including modified properties to adjust zonal transmissivity of the window 305 that may be used to counteract the non-uniform curing illustrated in FIG. 2A. FIG. 3B is a chart 330 depicting a comparison of the film thickness delta 232 (e.g., shrinkage) of FIG. 2A compared to the film thickness delta 333 (e.g., shrinkage) of a film cured by window 305 of FIG. 3A.

Altering the transmissivity of the window 305 alters the amount of energy that may pass through the window 305. Thus, by altering the transmissivity of the window 305, film shrinkage and non-uniformity can be controlled. For example, by decreasing the transmissivity of the window 305 at a location, the film shrinkage experienced at the corresponding location on the wafer is decreased. Similarly, as the transmissivity is increased, the shrinkage is increased. In one or more embodiments, the transmissivity of the window 305 varies by wavelength. As one non-limiting example, the window 305 may have a transmissivity of about 90% at a wavelength of 200 nanometers (nm) and may have a transmissivity of about 70% at a wavelength of about 2500 nanometers (nm).

FIG. 3A illustrates an exemplary window 305 with zones 308, 309, and 310 including modified properties to adjust transmissivity which may be used in the same or similar processing chamber that was used to cure the film 207 on wafer 202 of FIG. 2A.

Accordingly, zone 308 corresponds to location 208 of the wafer 202 of FIG. 2A, zone 309 corresponds to location 209 of the wafer 202 of FIG. 2A, and zone 310 corresponds to location 210 of the wafer 202 of FIG. 2A. In one or more embodiments, a zone corresponds to a location where energy (e.g., UV) that passes through that zone heats that location on the wafer. For instance, in one or more embodiments, the energy that passes through zone 308 heats location 208 on the wafer 202, the energy that passes through zone 309 heats location 209 on the wafer 202, and the energy that passes through zone 310 heats location 210 on the wafer 202.

For example, in a window 305 that is flat, the zones 308, 309, 310 may have the same or similar radial boundaries as those described for their respective locations. In one or more embodiments including a domed (e.g., not flat) window, the zones 308, 309, 310 have radial boundaries that correlate to the energy that would pass through the window 305 to hit the respective locations 208, 209, 210.

Because each zone 308, 309, 310 corresponds to each location 208, 209, 210, the transmissivity of each zone 308, 309, 310 controls the amount of energy that each respective location 208, 209, 210 experiences.

Accordingly, the properties of the window 305 at each zone 308, 309, 310 may be modified to control the amount of energy experienced at each corresponding location 208, 209, 210 to control the film shrinkage. As a non-limiting example, based on the shrinkage of the film 207 of the wafer 202 of FIG. 2A, zone 308 of the window 305 has been modified such that zone 308 has the lowest transmissivity of the zones 308, 309, 310 of the window 305 because location 208 experienced the largest film shrinkage. Similarly, the properties at zone 310 of the window 305 has been modified such that zone 310 has the highest transmissivity of the zones 308, 309, 310 of the window 305 because location 210 experienced the least film shrinkage. Finally, the properties at zone 309 of the window 305 has been modified such that zone 309 has a transmissivity more than that of zone 308 but less than zone 310 of the window 305 because location 209 experienced an intermediate level of film shrinkage. In sum, the properties of the window 305 at each zone 308, 309, 310, are altered to alter the transmissivity to make the shrinkage across the locations 208, 209, 210 uniform.

As another non-limiting example, location 210 may experience the most shrinkage, location 208 may experience the least shrinkage, and location 209 may experience an intermediate amount of shrinkage. Accordingly, zone 310 may be modified to be the least transmissive, zone 308 may be made the most transmissive, and zone 309 may be modified to be an intermediate level of transmissive.

As another non-limiting example, location 209 may experience the most amount of shrinkage, location 210 may experience the least amount of shrinkage, and location 208 may experience an intermediate amount of shrinkage. Accordingly, zone 309 may be modified to be the least transmissive, zone 310 may be the most transmissive, and zone 308 being modified to be an intermediate level of transmissive.

As another non-limiting example, location 209 may experience the most amount of shrinkage, location 208 may experience the least amount of shrinkage, and location 209 may experience an intermediate amount of shrinkage. Accordingly, zone 309 may be modified to be the least transmissive, zone 308 may be the most transmissive, and zone 310 being modified to be an intermediate level of transmissive.

As previously discussed, the transmissivity of the window 305 may vary by wavelength. As such, in one or more embodiments, the transmissivity of the zones 308, 309, 310 may be modified based on a desired transmissivity at a certain wavelength. For instance, the transmissivity of zones 308, 309, 310 may be modified based on a desired transmissivity at a wavelength of about 200 nanometers (nm) to about 400 nanometers (nm).

In one or more embodiments, the transmissivity of any zone 308, 309, 310 may be modified to be between about 0% to about 100% transmissive allowing between 0% and 100% of the energy emitted by the heating sources to pass through the zones 308, 309, 310. In one or more embodiments, the transmissivity of any zone 308, 309, 310 may be modified to be between about 0% to about 100% transmissive at wavelengths from about 200 nanometers (nm) to about 400 nanometers (nm), such as about 0% to about 90% at wavelengths from about 200 nanometers (nm) to about 400 nanometers (nm). As a non-limiting example, zone 308 may be modified to be about 25% or more transmissive, such as 50% or more transmissive, 75% or more transmissive, 80% or more transmissive, 85% or more transmissive, 90% or more transmissive, or 95% or more transmissive. As another example, zone 309 may be modified to be about 25% or more transmissive, such as 50% or more transmissive, 75% or more transmissive, 80% or more transmissive, 85% or more transmissive, 90% or more transmissive, or 95% or more transmissive. As another example, zone 310 may be modified to be about 25% or more transmissive, such as 50% or more transmissive, 75% or more transmissive, 80% or more transmissive, 85% or more transmissive, 90% or more transmissive, or 95% or more transmissive.

In one or more embodiments, the modification of transmissivity of a given zone 308, 309, 310 may vary with wavelength. As one example, a zone 308, 309, 310 may be modified to be about 78% at a wavelength of about 200 nanometers (nm) but be about 93% at a wavelength of about 1000 nanometers (nm). As another example, a zone 308, 309, 310 may be modified to be about 86% at a wavelength of about 200 nanometers (nm) but be about 95% at a wavelength of about 1000 nanometers (nm). As another example, a zone 308, 309, 310 may be modified to be about 90% at a wavelength of about 200 nanometers (nm) but be about 94% at a wavelength of about 1000 nanometers (nm).

FIG. 3B illustrates an exemplary chart 330 comparing the film thickness delta 232 of FIG. 2B to a film thickness delta 332 of an exemplary wafer utilizing the window 305 of FIG. 3A.

FIG. 3B compares the film thickness delta (e.g., shrinkage) 232 of the wafer 202 of FIG. 2A to a film thickness delta (e.g., shrinkage) 332 of an exemplary wafer utilizing the window 305 of FIG. 3A if all other operating parameters were held constant. In other words, FIG. 3B illustrates how window 305 may be used to modify non-uniform film thicknesses due to non-uniform shrinkage occurring during curing.

As previously indicated, window 305 includes modified transmissivity due to the modification of properties of the window 305 at zones 308, 309, and 310 which correspond to locations 208, 209, and 210, respectively. Accordingly, the amount of energy (e.g., UV) that is allowed to transmit through each of these zones 308, 309, 310 has been modified or controlled. Thus, during a substrate process utilizing energy transmission through the window 305, such as a curing process, the heating experienced by the wafer at each location 208, 209, 210 is also modified or controlled. By modifying or controlling the heating experienced by the wafer at discrete locations, such as locations 208, 209, 210, the film shrinkage occurring at each location 208, 209, 210 is also modified or controlled. By controlling or modifying the film shrinkage at each discrete locations based on known or obtainable film thickness non-uniformity, subsequent film thickness uniformity can be improved.

In the illustrated embodiment, the transmissivity at the zone 310 has been increased, thus increasing film shrinkage 323 at location 210, the transmissivity at zone 309 has been held relatively constant thus holding film shrinkage 323 at location 309 relatively constant, and the transmissivity at zone 308 has been decreased thus decreasing film shrinkage 323 at location 209. Accordingly, the film shrinkage 323, and resulting film thickness, is more uniform as compared to film shrinkage 232, and resulting film thickness of the wafer 202 of FIG. 2A.

While window 305 illustrates zones 308, 309, and 310 at certain locations, it is contemplated that there may be any number of zones where properties affecting transmissivity are altered and the zones may be in any location so long as they correspond to the locations of varying shrinkage of a wafer being processed. For example, there may be one, two, three, four, five, six, or more zones that may be symmetric about the center of a wafer or may be elsewhere. For instance, in one or more embodiments, the zones may or may not be concentric about the center of the wafer. Similarly, in one or more embodiments, the zones are not necessarily circular and may be square, triangular, polygonal, or amorphous.

Similarly, it is contemplated that there may be zones where the properties of the window 305 are not altered thus leaving the transmissivity of said zones unaltered.

In one or more embodiments, the locations 208, 209, and 210 may be empirically determined. That is, the locations (such as locations 208, 209, and 210 of FIG. 2A) in which the shrinkage varies across the wafer 202 and the amount of shrinkage experienced at each location may be empirically determined.

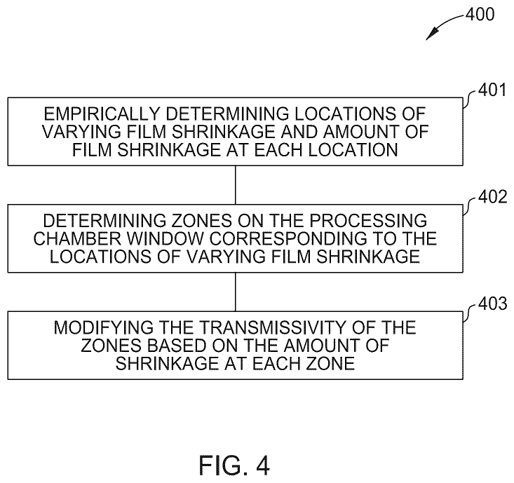

FIG. 4 illustrates a method 400 for controlling the shrinkage of a film (such as films 107 and 207 of FIGS. 1 and 2A) on a wafer (such as wafers 102 and 202).

At operation 401 locations (such as locations 208, 209, and 210 of FIGS. 2A-2B) of varying shrinkage and amount of varying shrinkage are determined. In one or more embodiments, the locations and amounts are empirically determined. In one or more embodiments, empirically determining the locations of varying shrinkage and amount of varying shrinkage includes curing a wafer (such as wafer 202 of FIG. 2A) in a processing chamber (such as processing chamber 100) with a window (such as windows 105 and 305 of FIGS. 1 and 3A) with a known transmissivity. The varying locations of shrinkage and amount of shrinkage may then be measured.

At operation 402, zones (such as zones 308, 309, and 310 of FIGS. 3A-3B) of the window corresponding to the locations the wafer are determined. In one or more embodiments, a zone corresponds to a location where energy (e.g., UV) that passes through that zone heats that location on the wafer. In one or more embodiments, the window is flat and the zones are located at the same position on the window as the locations are located on the wafer. In one or more embodiments, the window is domed and the zones may not be located at the same position on the window as the locations are located on the wafer.

At operation 403, the transmissivity of the zones is modified based on the amount of shrinkage determined at operation 401 to modify the amount of energy that may pass through each zone. In one or more embodiments, the amount of energy that may pass through each zone correlates to the amount of heating experienced by a corresponding location on the wafer. Similarly, in one or more embodiments, the amount of heating experienced by the location on the wafer correlates to the amount of shrinkage experienced by the film at the location. Accordingly, in one or more embodiments, operation 403 may also include determining the correlation between energy transmissivity and film shrinkage

As a non-limiting example, decreasing the transmissivity at a zone decreases the amount of energy that may pass through a particular zone which decreases the amount of heat experienced by the film at the corresponding location on the wafer which decreases the film shrinkage experience experienced by the film at the corresponding location on the wafer which increases the film thickness at the corresponding location. Similarly, as a non-limiting example, increasing the transmissivity at a zone increases the amount of energy that may pass through a particular zone which increases the amount of heat experienced by the film at the corresponding location on the wafer which increases the film shrinkage experience experienced by the film at the corresponding location on the wafer which decreases the film thickness at the corresponding location

In one or more embodiments, the transmissivity of each zone is modified such that when another film on another wafer is cured in the processing chamber utilizing the same processing parameters, the shrinkage is more uniform than the film on the first wafer. For instance, the transmissivity of a zone of the window corresponding to a location on the first wafer that experienced more shrinkage may be increased to more than the transmissivity of a zone of the window corresponding to a location on the first wafer that experienced less shrinkage.

In one or more embodiments, modifying the transmissivity of the zones includes selectively acid etching one or more of the zones to modify the properties of the window at the zones to modify the transmissivity of the window at the zones. In one or more embodiments, acid etching the window results in an increased surface roughness of the window. The increased surface roughness of the window reduces the transmissivity of the window.

In one or more embodiments, the acid etching may include using an acid to etch the window. In one or more embodiments, acid etching includes pre-polishing the window in the zones to be etched so that the zones are more sensitive to etching. In one or more embodiments, after pre-polishing the window, the window is rinsed in the acid to etch the window. In one or more embodiments, the acid used is an acid designed to etch the material the window is made of. In one or more embodiments, the window is made of fused silica glass and the acid comprises hydrofluoric acid.

In one or more embodiments, the surface roughness and resulting transmissivity of the zone being etched may be controlled by controlling the amount of time that the zone is etched. As one example, without being bound by theory, increasing the amount of time that a zone is being etched increases the surface roughness and decreases the percent transmissivity of the zone being etched. Accordingly, by etching a zone for a particular amount of time, the transmissivity of the zone may be controlled. For instance, there may be a known correlation between the amount of time the window is etched and the percent decrease of transmissivity and that correlation may be used to select etching times for particular zones.

In one or more embodiments, modifying the transmissivity of the zones includes selectively using one or more lasers to treat the one or more of the zones thus modifying the properties of the window at the zones and modifying the transmissivity of the window at the zones. In one or more embodiments, laser treating the window can surface etch the window surface and/or etch the internal structure of the window.

In one or more embodiments, laser process parameters include, but are not limited to, laser wavelength, pulse width, beam profile, average power, pulse frequency, number of pulses in a burst, focal spot size, number of process passes.

In one or more embodiments, the surface etching and/or internal structure etching and resulting transmissivity of the zone may be controlled by controlling the power density of the one or more lasers used to treat that the zone is etched. In one or more embodiments, the laser pulse energy (e.g., the laser average power divided by pulse frequency) is in the range of about 3 microjoules (uJ) to about 50 microjoules (uJ), such as in the range of 5 microjoules (uJ) to 20 microjoules (uJ).

In one or more embodiments, laser pulse repetition frequency impacts the process speed or density of ablation spots. The spot-to-spot pitch is the ratio of scan speed to pulse frequency. As one example, at a given scan speed, laser pulse repetition frequency may be used to increase the ablation spot to ablation spot pitch to control the transmissivity. For instance, an ultrashort pulsed laser with a pulse width in the range of about 50 femtoseconds (fs) to about 10 picoseconds (ps), a wavelength of about 250 nanometers (nm) to about 1.3 micrometers (um), and a pulse repetition frequency in the range of 50 megahertz (MHz) to 2 gigahertz (GHz) with a pulse burst output capability can be used.

Many different types of lasers may be used to pattern the surface for modifying transmissivity. As one example, the laser may be a pulsed carbon dioxide (CO2) laser with a wavelength in the range of about 9 um to about 11 um. According to another example, the laser may be a pulsed solid state laser with a pulse in the range of about 20 fs to about 50 ns with a wavelength of about 1 um to about 1.5 um infrared, about 520 nm to about 540 nm green, or less than about 360 nm ultraviolet (UV). As another example, the laser may be a femtosecond green laser with a wavelength of about 532 nm, a pulse width of around 550 fs, a seed pulse frequency of about 500 MHz, and a focal spot size of about 7.5 um to about 15 um, such as about 13 um. Such a laser may result in crater like etching with a diameter of about 10 um and a depth of about 1.2 um when the laser is pulsed once per burst and a depth of 3 um when the laser is pulsed 2.5 times per burst.

According to one mode of operation, laser etching includes setting an unprocessed window into a linear stage and passing a laser through an optical beam expander and a collimator to direct the laser into a beam scanner and a focus lens. In one or more embodiments, the beam expander and collimator set the beam diameter and collimates laser before the laser enters the scanner. In one or more embodiments, the scanner is a galvo scanner or a polygon scanner or a galvo/polygon hybrid scanner. In one or more embodiments, the focus lens delivers desired laser focal spot size onto the window and the linear stage is used to position and align the window under the scan field.

As one example, without being bound by theory, increasing the power of the lasers used in a laser treatment for a particular zone increases the etching by the lasers and decreases the percent transmissivity of the zone being treated. Accordingly, by etching a zone for with a laser of a particular power, the transmissivity of the zone may be controlled. As another example, without being bound by theory, increasing the density of the lasers used in a laser treatment for a particular zone also increases the etching by the lasers and decreases the percent transmissivity of the zone being treated. Similarly, in one or more embodiments, the transmissivity of the zones may be further controlled by controlling whether the surface is being etched, the internal structure is being etched, and at what depth the internal structure is being etched.

The present disclosure contemplates that one or more operations of the method 400 can be used in relation to processing other than film curing (such as substrate deposition or etching).

Benefits of the present disclosure include more uniform processing (such as film cure on wafers), increased throughput, and enhanced device performance. It is contemplated that one or more portions of the subject matter disclosed herein may be combined. As an example, one or more aspects, features, components, operations, and/or properties of the various implementations of the processing system 100 illustrated in FIG. 1, the wafer 202 in FIG. 2A, the window 305 in FIG. 3A, and/or the method 400 in FIG. 4 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A window for use in a processing chamber applicable for use in semiconductor manufacturing, comprising:
a first zone disposed between a first radius and a second radius including a first transmissivity; and
a second zone disposed between the second radius and a third radius including a second transmissivity.

2. The window of claim 1, further comprising a third zone between the third radius and a fourth radius including a third transmissivity.

3. The window of claim 2, wherein the third transmissivity is less than the second transmissivity.

4. The window of claim 2, wherein the third transmissivity is greater than the first transmissivity.

5. The window of claim 2, wherein the first radius is at a center of the window.

6. The window of claim 1, wherein the first zone includes a first surface roughness and the second zone includes a second surface roughness.

7. The window of claim 6, wherein the first zone includes a first etched internal structure and the second zone includes a second etched internal structure.

8. A processing chamber applicable for use in semiconductor manufacturing, comprising:
a chamber body at least partially defining an internal volume;
a pedestal disposed within the internal volume;
one or more heat sources disposed within the internal volume and configured to emit energy towards the pedestal; and
a window disposed between the one or more heat sources and the pedestal, wherein the energy emitted by the one or more heat sources passes through the window, the window comprising:
a first zone including a first transmissivity; and
a second zone including a second transmissivity, wherein the first transmissivity is less than the second transmissivity.

9. The processing chamber of claim 8, wherein the first zone includes a first surface roughness and the second zone includes a second surface roughness, wherein the first surface roughness is less than the second surface roughness.

10. The processing chamber of claim 8, wherein the first zone includes a first etched internal structure and the second portion includes a second etched internal structure.

11. A method of manufacturing a substrate processing chamber comprising:
determining a film disposed on a wafer in a processing chamber experiences non-uniform film shrinkage from one or more heat sources emitting energy through one or more windows, wherein the non-uniform film shrinkage includes a first film shrinkage at a first location on the wafer and a second film shrinkage at a second location on the wafer; and
modifying a transmissivity a first zone of the one or more windows corresponding to the first location on the wafer.

12. The method of claim 11, further comprising modifying a transmissivity of a second zone of the one or more windows corresponding to the second location on the wafer.

13. The method of claim 12, wherein modifying the transmissivity of the first zone comprises acid etching the first zone of the one or more windows to increase the surface roughness of the first zone, and wherein modifying the transmissivity of the second zone comprises acid etching the second zone of the one or more windows to increase the surface roughness of the second zone.

14. The method of claim 13, wherein the first zone is acid etched for a first amount of time and the second zone is acid etched for a second amount of time, wherein the second amount of time is longer than the first amount of time, and wherein the resulting transmissivity of the second zone is less than the resulting transmissivity of the first zone.

15. The method of claim 12, wherein modifying the transmissivity of the first zone comprises laser treating the first zone of the one or more windows.

16. The method of claim 15, wherein laser treating the first zone of the one or more windows increases the surface roughness of the first zone.

17. The method of claim 15, wherein laser treating the first zone of the one or more windows etches the internal structure of the first zone.

18. The method of claim 17, wherein modifying the transmissivity of the second zone comprises laser treating the second zone.

19. The method claim 18, wherein the first zone is laser treated by one or more lasers utilizing a first laser power and the second zone is laser treated by the one or more lasers utilizing a second laser power, wherein the first laser power is less than the second laser power, and wherein the resulting transmissivity of the second zone is less than the resulting transmissivity of the first zone.

20. The method claim 18, wherein the first zone is laser treated by one or more lasers utilizing a first laser density and the second zone is laser treated by the one or more lasers utilizing a second laser density, wherein the first laser density is less than the second laser density, and wherein the resulting transmissivity of the second zone is less than the resulting transmissivity of the first zone.
